(19) United States
(12) Patent Application Publication
(10) Pub. No.: US 2023/0100791 A1
(43) Pub. Date: Mar. 30, 2023

(54) ARTICLES HAVING REMOVABLE COATINGS AND RELATED METHODS

(71) Applicant: ENTEGRIS, INC., Billerica, MA (US)

(72) Inventor: Carlo Waldfried, Middleton, MA (US)

(21) Appl. No.: 17/950,909

(22) Filed: Sep. 22, 2022

Related U.S. Application Data
(60) Provisional application No. 63/250,475, filed on Sep. 30, 2021.

(51) Int. Cl. C23C 16/02; C23C 16/04; C23C 16/455

(52) U.S. Cl. CPC C23C 16/0236; C23C 16/042; C23C 16/45555

(57) ABSTRACT

Some embodiments relate to articles having removable coatings. The articles may comprise a substrate and a coating on the substrate. An etch stop layer may be provided between the substrate and the coating to permit removal of the coating without damaging the substrate. Some embodiments relate to methods for removing a coating from an article. The methods may comprise obtaining an article comprising an etch stop layer between a substrate and a coating on the substrate, and removing at least a portion of the coating from the article. Other embodiments further provide articles and related methods.

### CROSS-REFERENCE TO RELATED APPLICATIONS

This application claims the benefit under 35 USC 119 of U.S. Provisional Patent Application No. 63/250,475, filed Sep. 30, 2021, the disclosure of which is hereby incorporated herein by reference in its entirety.

### FIELD

The present disclosure generally relates to articles having removable coatings and related methods.

### BACKGROUND

Semiconductor fabrication processes utilize coated substrates. The coating and the substrate typically have similar chemical compositions to ensure that the coating adheres to the substrate. However, being chemically similar to the substrate, the coating cannot be removed without causing damage to the substrate.

### SUMMARY

In a first aspect a method for removing a coating from an article is disclosed, the method including: obtaining an article, wherein the article includes: a substrate, wherein the substrate includes a magnesium-containing metal body, wherein the magnesium-containing metal body includes a first metal component; a coating, wherein the coating includes a second metal component; and an etch stop layer, wherein the etch stop layer includes magnesium fluoride and is located between the magnesium-containing metal body and the coating; and removing at least a portion of the coating from the article.

A second aspect according to the first aspect, wherein the substrate includes at least one of a plenum, a trench, a structure defining a hole, a structure defining a channel, a structure defining a cavity, or any combination thereof.

A third aspect according to any of the preceding aspects, wherein the substrate is not a wafer substrate.

A fourth aspect according to any of the preceding aspects, wherein the substrate is not an integrated circuit.

A fifth aspect according to any of the preceding aspects, wherein the coating is at least one of: a coating that has been chemically modified from a previous state, a coating having a surface that has been modified from a previous state, a coating having a thickness that has been modified from a previous state, a coating having a non-uniform thickness, a coating not meeting a specification for an application, a coating having a fabrication defect, or any combination thereof.

A sixth aspect according to any of the preceding aspects, wherein the second metal component and the first metal component both include at least one of magnesium, aluminum, vanadium, iron, nickel, chromium, zinc, molybdenum, titanium, lithium, copper, manganese, silicon, copper, manganese, or any combination thereof.

A seventh aspect according to any of the preceding aspects, wherein the first metal component includes aluminum; and the second metal component includes aluminum.

An eighth aspect according to any of the preceding aspects, wherein the etch stop layer is an etch stop region located at and below a surface of the substrate.

A ninth aspect according to any of the preceding aspects, wherein the removing includes contacting the coating with an etchant.

A tenth aspect according to any of the preceding aspects, wherein the etchant removes at least a portion of the etch stop layer.

An eleventh aspect according to any of the preceding aspects, wherein the method further including: exposing the article to a reactive gas phase to reform at least a portion of the etch stop layer, wherein the reactive gas phase includes a fluorine component.

A twelfth aspect according to any of the preceding aspects, wherein the fluorine component includes or is derived from at least one of CF₄, C₂F₄, C₃F₆, C₄F₈, CHF₃, C₂H₂F₂, C₂F₆, HF, CH₃F, polymerized perfluoroalkylethylene having a C₁-C₁₀ perfluoroalkyl group, polytetrafluoroethylene (PTFE), tetrafluoroethylene/perfluoro(alkyl vinyl ether) copolymer (PFA), tetrafluoroethylene/hexafluoropropylene copolymer (FEP), tetrafluoroethylene/perfluoro(alkyl vinyl ether)/hexafluoropropylene copolymer (EPA), polyhexafluoropropylene, ethylene/tetrafluoroethylene copolymer (ETFE), poly trifluoroethylene, polyvinylidene fluoride (PVDF), polyvinyl fluoride (PVF), polychlorotrifluoroethylene (PCTFE), ethylene/chlorotrifluoroethylene copolymer (ECTFE), or any combination thereof.

A thirteenth aspect according to any of the preceding aspects, wherein the fluorine component of the reactive gas phase reacts with magnesium present within the magnesium-containing metal body to reform the etch stop layer.

A fourteenth aspect according to any of the preceding aspects, wherein a ratio of a thickness of coating removed to a thickness of etch stop layer removed is at least 2:1.

A fifteenth aspect according to any of the preceding aspects, wherein the etch stop layer has a uniform thickness.

A sixteenth aspect according to any of the preceding aspects, wherein the method further including forming a replacement coating on the etch stop layer.

A seventeenth aspect according to any of the preceding aspects, wherein the replacement coating is a thermal atomic layer deposition (ALD) coating.

An eighteenth aspect according to any of the preceding aspects, wherein the replacement coating includes at least one of alumina, yttria, titania, zirconia, tantalum oxide, or any combination thereof.

A nineteenth aspect disclosed herein is a method for forming an article, the method including: obtaining a substrate, wherein the substrate includes a magnesium-containing metal body, wherein the magnesium-containing metal body includes a first metal component; exposing the substrate to a reactive gas phase to form an etch stop layer at and below a surface of the substrate, wherein the reactive gas phase includes a fluorine component that reacts with magnesium of the magnesium-containing metal body to form magnesium fluoride; and forming a coating on the etch stop layer, wherein the coating includes a second metal component.

A twentieth aspect disclosed herein is to an article including: a substrate, wherein the substrate includes a magnesium-containing metal body, wherein the magnesium-containing metal body includes a first metal component, wherein the substrate is not a wafer substrate, wherein the substrate is not an integrated circuit; a coating, wherein the coating includes a second metal component; and an etch stop layer located between the substrate and the coating, wherein the etch stop layer includes magnesium fluoride formed at and below a surface of the substrate.

### BRIEF DESCRIPTION OF THE DRAWINGS

Reference is made to the drawings that form a part of this disclosure, and which illustrate embodiments in which the materials and methods described herein can be practiced.

FIG. 1 is a flowchart of a method for forming an article, according to some embodiments of the present disclosure.

FIG. 2 is a schematic diagram of an article, according to some embodiments of the present disclosure.

FIG. 3 is a flowchart of a method for removing a coating from an article, according to some embodiments of the present disclosure.

FIG. 4 is a schematic diagram of a method for (A) forming an article, (B) reworking the article, and (C) refurbishing the article, according to some embodiments of the present disclosure.

### DETAILED DESCRIPTION

Some embodiments relate to articles having removable coatings and related methods. The articles may include an etch stop layer between a substrate and a coating, which may be chemically similar to the substrate. The etch stop layer may be resistant to chemicals and other substances employed in coating removal processes, such that the coating may be removed without causing a change to the substrate that would render the article unsuitable for commercial purposes. Examples of such changes to the substrate may include, without limitation, a modified surface finish, an altered visual appearance, a change in chemical composition, a change in surface morphology, etc. The etch stop layers may provide sufficient adhesion between the substate and the coating. The etch stop layer may be a highly conformal layer with complete surface coverage of high aspect ratio features of the substrate. The etch stop layers may exhibit thermal stability at high temperatures.

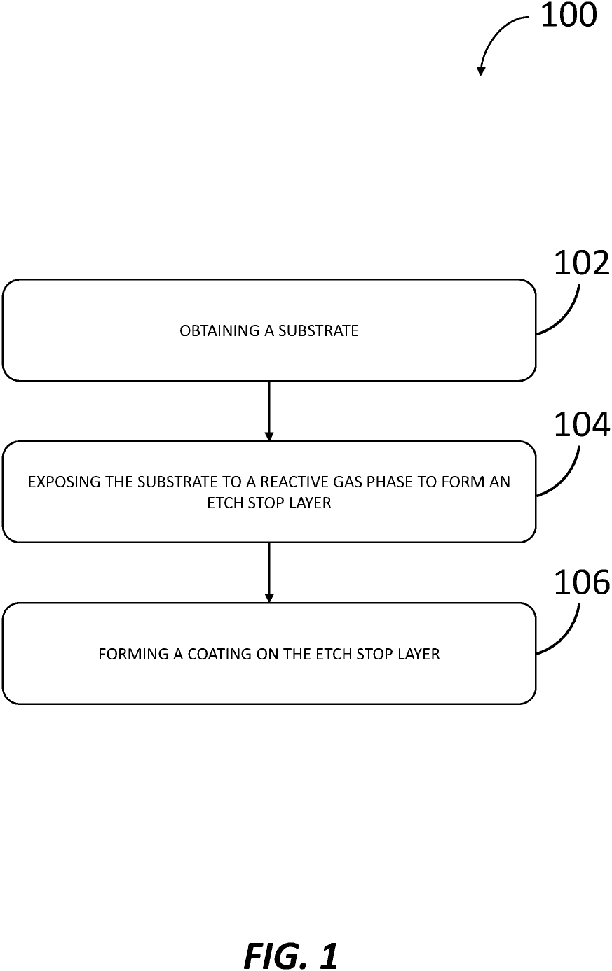

FIG. 1 is a flowchart of a method for forming an article including a removable coating, according to some embodiments of the present disclosure. As shown in FIG. 1, the method 100 may comprise one or more of the following steps: a step 102 of obtaining a substrate, a step 104 of exposing the substrate to a reactive gas phase to form an etch stop layer, and a step 106 of forming a coating on the etch stop layer.

At step 102, in some embodiments, the substrate may be obtained. In some embodiments, the substrate may be a metal body comprising one or more metal components. In some embodiments, each of the one or more metal components may comprise, consist of, or consist essentially of at least one of elemental metal, a metal alloy, a metal compound (e.g., a metal oxide compound), or any combination thereof. In some embodiments, each of the one or more metal components may comprise, consist of, or consist essentially of at least one of magnesium, aluminum, vanadium, iron, nickel, chromium, zinc, molybdenum, titanium, lithium, copper, manganese, or any combination thereof. In some embodiments, each of the one or more metal components may be selected from the group consisting of at least one of magnesium, aluminum, vanadium, iron, nickel, chromium, zinc, molybdenum, titanium, lithium, copper, manganese, silicon, copper, manganese, magnesium oxide, or any combination thereof. In some embodiments, the substrate may comprise, consist of, or consist essentially of at least one of a magnesium component, an aluminum component, or any combination thereof.

In some embodiments, the substrate may be a magnesium-containing metal body. In some embodiments, the magnesium-containing metal body may comprise, consist of, or consist essentially of a magnesium-containing metal (e.g., any metal or metal alloy comprising any amount of magnesium, including a trace amount of magnesium). In some embodiments, the magnesium-containing metal may comprise, consist of, or consist essentially of a first metal component, such as a first aluminum component. In some embodiments, the magnesium-containing metal body may comprise a magnesium-containing alloy. In some embodiments, the magnesium-containing alloy may comprise, consist of, or consist essentially of a first metal component, such as a first aluminum component. In some embodiments, the magnesium-containing metal alloy may comprise, consist of, or consist essentially of, or may be selected from the group consisting of, at least one of the following: an iron alloy (e.g., steel or stainless steel), an aluminum alloy, a vanadium alloy, a magnesium alloy (e.g., stainless magnesium, such as an alloy comprising magnesium and lithium, or an alloy comprising magnesium and aluminum, etc.), a nickel alloy, a chromium alloy, a zinc alloy, a titanium alloy, or any combination thereof.

In some embodiments, the magnesium component may comprise a mobile form of magnesium. For example, in some embodiments, the magnesium component may comprise magnesium in a metallic form as a metal alloy, a metal ion, a metallic oxide, elemental magnesium, or any combination thereof. In some embodiments, the magnesium component comprises at least one of a magnesium-containing metal alloy, a magnesium ion, a magnesium-containing metal oxide, elemental magnesium, or any combination thereof.

In some embodiments, the substrate may comprise at least 0.01% to less than 100% by weight of magnesium based on a total weight of the substrate, or any range or subrange therebetween. For example, in some embodiments, the substrate may comprise at least 0.01%, at least 0.1%, at least 1%, at least 10%, at least 20%, at least 30%, at least 40%, at least 50%, at least 60%, at least 70%, at least 80%, at least 90%, at least 99%, no greater than 99%, no greater than 90%, no greater than 80%, no greater than 70%, no greater than 60%, no greater than 50%, no greater than 40%, no greater than 30%, no greater than 20%, no greater than 10%, no greater than 1%, no greater than 0.1%, no greater than 0.01%, greater than 0% to 100%, greater than 10% to 100%, greater than 20% to 100%, greater than 30% to 100%, greater than 40% to 100%, greater than 50% to 100%, greater than 60% to 100%, greater than 70% to 100%, greater than 80% to 100%, greater than 90% to 100%, greater than 0% to 90%, greater than 0% to 80%, greater than 0% to 70%, greater than 0% to 60%, greater than 0% to 50%, greater than 0% to 40%, greater than 0% to 30%, greater than 0% to 20%, greater than 0% to 10%, greater than 0% to 5%, greater than 0% to 1%, greater than 0.01% to 1%, greater than 0.1% to 1%, 40% to 99%, 40% to 95%, 40% to 90%, 40% to 80%, 40% to 70%, 40% to 60%, 50% to 99%, 60% to 99%, 70% to 99%, 80% to 99%, 90% to 99%, 95% to 99%, and/or any range or subrange therebetween, by weight of magnesium based on the total weight of the substrate.

In some embodiments, the substrate may comprise 1% by weight or less of magnesium oxide (MgO) based on the total weight of the substrate. In some embodiments, the substrate may comprise 0.5% by weight or less of magnesium oxide based on the total weight of the substrate. In some embodiments, the substrate may comprise 0.1% by weight or less of magnesium oxide based on the total weight of the substrate. In some embodiments, the substrate may comprise 0.05% by weight or less of magnesium oxide based on the total weight of the substrate.

In some embodiments, the substrate may comprise at least 0.01% to less than 100% by weight of aluminum based on the total weight of the substrate. For example, in some embodiments, the substrate may comprise at least 0.01%, at least 0.1%, at least 1%, at least 10%, at least 20%, at least 30%, at least 40%, at least 50%, at least 60%, at least 70%, at least 80%, at least 90%, at least 99%, no greater than 99%, no greater than 90%, no greater than 80%, no greater than 70%, no greater than 60%, no greater than 50%, no greater than 40%, no greater than 30%, no greater than 20%, no greater than 10%, no greater than 1%, no greater than 0.1%, no greater than 0.01%, greater than 0% to less than 100%, greater than 10% to less than 100%, greater than 20% to less than 100%, greater than 30% to less than 100%, greater than 40% to less than 100%, greater than 50% to less than 100%, greater than 60% to less than 100%, greater than 70% to less than 100%, greater than 80% to less than 100%, greater than 90% to less than 100%, greater than 0% to 90%, greater than 0% to 80%, greater than 0% to 70%, greater than 0% to 60%, greater than 0% to 50%, greater than 0% to 40%, greater than 0% to 30%, greater than 0% to 20%, greater than 0% to 10%, greater than 0% to 5%, greater than 0% to 1%, and/or any range or subrange therebetween, by weight of aluminum based on the total weight of the substrate.

In some embodiments, the aluminum alloy may comprise at least one of aluminum, magnesium, silicon, iron, copper, chromium, zinc, titanium, manganese, or any combination thereof. In some embodiments, the aluminum alloy comprise, consist of, or consist essentially of at least one of 96% to 98% by weight of aluminum based on the total weight of the aluminum alloy, 0.5% to 1.2% by weight of magnesium based on the total weight of the aluminum alloy, 0.4% to 0.8% by weight of silicon based on the total weight of the aluminum alloy, greater than 0% to 0.7% by weight of iron based on the total weight of the aluminum alloy, 0.1% to 0.4% by weight of copper based on the total weight of the aluminum alloy, greater than 0% to 0.4% by weight of chromium based on the total weight of the aluminum alloy, greater than 0% to 0.3% by weight of zinc based on the total weight of the aluminum alloy, greater than 0% to 0.3% by weight of titanium based on the total weight of the aluminum alloy, greater than 0% to 0.2% by weight of manganese based on the total weight of the aluminum alloy, or any combination thereof. In some embodiments, the aluminum alloy may further comprise at least one of the following: one or more metals, one or more transition metals, one or more semiconductor materials, or any combination thereof. In some embodiments, the one or more semiconductor materials may comprise a compound comprising at least one of gallium, antimony, tellurium, arsenic, polonium, or any combination thereof.

In some embodiments, the substrate may comprise, consist of, or consist essentially of at least one of the following: 10% to 99% by weight of nickel based on the total weight of the substrate, 40% to 99% by weight of vanadium based on the total weight of the substrate, 15% to 99% by weight of chromium based on the total weight of the substrate, 40% to 99% by weight of aluminum based on the total weight of the substrate, 40% to 99% by weight of zinc based on the total weight of the substrate, 40% to 99% by weight of titanium based on the total weight of the substrate, greater than 0% to less than 100% by weight of iron based on the total weight of the substrate, 2% to 3% by weight of molybdenum based on the total weight of the substrate, or any combination thereof. In some embodiments, the weight percentages above pertain to metal components comprising the metal or the metals in elemental form.

In some embodiments, the substrate may have at least one feature. In some embodiments, the at least one feature may comprise, consist of, or consist essentially of, or may be selected from the group consisting of, a plenum, a trench, a structure defining a hole, a structure defining an opening, a structure defining a pore channel, a structure defining a cavity (e.g., a partially enclosed region defining a cavity), a planar surface, a non-planar surface, or any combination thereof. In some embodiments, the at least one feature may have an aspect ratio. For example, in some embodiments, the aspect ratio of a feature may refer to a ratio of a depth to a width. In some embodiments, the aspect ratio of a feature may refer to a ratio of a width to a depth. In some embodiments, the aspect ratio of a feature may refer to a ratio of two of a length, a width, or a height. In some embodiments, the aspect ratio of a feature may refer to a ratio of a depth to a diameter. In some embodiments, the aspect ratio of a feature may refer to a ratio of a diameter to a depth. In some embodiments, the aspect ratio of a feature may refer to a ratio of at least of the following: a width, a depth, a height, a diameter, and a circumference.

In some embodiments, the at least one feature may have an aspect ratio of 2:1 to 1000:1, or any range or subrange therebetween. For example, the at least one feature may have an aspect ratio of at least 2:1, at least 3:1, at least 4:1, at least 5:1, at least 6:1, at least 7:1, at least 8:1, at least 9:1, at least 10:1, at least 15:1, at least 20:1, at least 25:1, at least 30:1, at least 35:1, at least 40:1, at least 45:1, at least 50:1, at least 55:1, at least 60:1, at least 65:1, at least 70:1, at least 75:1, at least 80:1, at least 85:1, at least 90:1, at least 95:1, at least 100:1, at least 200:1, at least 300:1, at least 400:1, at least 500:1, at least 600:1, at least 700:1, at least 800:1, at least 900:1, to 1000:1, and/or any range or subrange therebetween.

In some embodiments, the substrate may not comprise a wafer substrate. In some embodiments, the substrate may not comprise a silicon wafer. In some embodiments, the substrate may not comprise an integrated circuit.

At step 104, in some embodiments, the substrate may be exposed to the reactive gas phase to form the etch stop layer. In some embodiments, the exposing may be performed under conditions sufficient to result in formation of the etch stop layer. In some embodiments, the exposing may be performed in a chamber configured to expose the reactive gas phase to the substrate. In some embodiments, the exposing may be performed in a process chamber. In some embodiments, the exposing may be performed in a reaction vessel. In some embodiments, the exposing may be performed by vaporizing a solid or liquid precursor material to obtain the reactive gas phase and supplying the reactive gas phase to the process chamber or the reaction vessel. In some embodiments, the exposing may be performed by supplying the reactive gas phase to the process chamber or reaction vessel (e.g., without vaporizing a solid or liquid precursor material to obtain the reactive gas phase). In some embodiments, the etch stop layer is formed by a plasma-free deposition process. In some embodiments, the etch stop layer is formed by a non-plasma deposition process.

In some embodiments, the reactive gas phase may comprise a fluorine component. In some embodiments, the reactive gas phase may comprise a molecular fluorine source vapor, which may be derived from a liquid or solid. In some embodiments, the fluorine component may comprise, consist of, or consist essentially of molecular fluorine. In some embodiments, the fluorine component is not ionic, substantially not ionic, not processed (e.g., by adding energy other than heat) to form plasma, or any combination thereof. In some embodiments, the fluorine component may comprise, consist of, or consist essentially of at least one of a fluorinated organic compound, a perfluorinated organic compound, or any combination thereof. In some embodiments, for example, the fluorine component may comprise, consist of, or consist essentially of at least one of a fluorinated alkane, a perfluorinated alkane, a fluorinated alkene, a perfluorinated alkene, or any combination thereof, wherein any one or more of which may be linear or branched. In some embodiments, the fluorine component may comprise, consist of, or consist essentially of, or may be selected from the group consisting of, at least one of CF₄, C₂F₄, C₃F₆, C₄F₈, CHF₃, C₂H₂F₂, C₂F₆, HF, CH₃F, or any combination thereof. In some embodiments, the reactive gas phase is distinct from plasma, processes for generating plasma, or any combination thereof.

In some embodiments, the reactive gas phase may comprise a gaseous fluorinated polymer derived from a non-gaseous fluorinated polymer (e.g., a solid or a liquid phase fluorinated polymer). In some embodiments, the fluorinated polymer may be a homopolymer or a copolymer. In some embodiments, the fluorinated polymer may comprise a copolymer of at least one fluoroolefin monomer and optionally at least one non-fluorinated co-monomer. In some embodiments, the fluorinated polymer may be fluorinated (i.e., partially fluorinated), perfluorinated, or may include non-fluorine halogen atoms, such as, for example and without limitation, chlorine. In some embodiments, a molecular fluorine source may be liquid or solid at room temperature, but that vaporizes at the process temperatures disclosed herein. Non-limiting examples of fluoropolymers include, without limitation, at least one of the following: polymerized perfluoroalkylethylene having a C₁-C₁₀ perfluoroalkyl group; polytetrafluoroethylene (PTFE); tetrafluoroethylene/perfluoro(alkyl vinyl ether) copolymer (PFA); tetrafluoroethylene/hexafluoropropylene copolymer (FEP); tetrafluoroethylene/perfluoro(alkyl vinyl ether)/hexafluoropropylene copolymer (EPA); polyhexafluoropropylene; ethylene/tetrafluoroethylene copolymer (ETFE); poly trifluoroethylene; polyvinylidene fluoride (PVDF); polyvinyl fluoride (PVF); polychlorotrifluoroethylene (PCTFE); ethylene/chlorotrifluoroethylene copolymer (ECTFE); or any combination thereof.

In some embodiments, the etch stop layer may comprise magnesium fluoride (MgF₂). In some embodiments, the magnesium fluoride of the etch stop layer may be a reaction product of a magnesium component present within the substrate and a fluorine component present in the reactive gas phase. In some embodiments, the magnesium fluoride of the etch stop layer may be formed at the surface of the substrate and below the surface of the substrate. For example, in some embodiments, the fluorine component may react with at least one of magnesium present at the surface of the substrate, magnesium present beneath the surface of the substrate, magnesium that diffuses or migrates from a bulk portion of the substrate to the surface or an area proximal to the surface, or any combination thereof. In some embodiments, the etch stop layer may not be a substantially discrete stratum formed on the surface of the substrate, but rather may be a region formed at, and optionally beneath, the surface of the substrate. In some embodiments, the etch stop layer is not (and is thus distinct from) a layer applied to a substrate surface via a coating process or a deposition process (e.g., chemical vapor deposition, atomic layer deposition, physical vapor deposition, etc.).

In some embodiments, the etch stop region may comprise, consist of, or consist essentially of at least one of a magnesium compound, a fluoride compound, a magnesium fluoride compound, an oxide compound, a metal compound, a metal oxide compound, or any combination thereof. In some embodiments, the etch stop region may comprise, consist of, or consist essentially of at least one of magnesium fluoride (MgF₂), a metal oxide compound, or any combination thereof. In some embodiments, the metal oxide compound may be a reaction product. For example, in some embodiments, the metal oxide compound may be formed upon exposure of the substrate to oxygen. In some embodiments, the etch stop layer may comprise, consist of, or consist essentially of an atomic layer deposition (ALD) coating comprising yttria. In some embodiments, the etch stop layer may comprise, consist of, or consist essentially of an ALD coating comprising zirconia. In some embodiments, the etch stop layer may comprise, consist of, or consist essentially of an ALD coating comprising titania. In some embodiments, the etch stop layer may comprise an ALD coating comprising AlOₓN_{y}, where x is 1 to 5 and N is 1 to 5.

In some embodiments, the exposing may be performed at one or more process conditions. In some embodiments, the process conditions may comprise at least one of a temperature of 200° C. to 500° C. (e.g., 350° C. to 500° C., 375° C. to 425° C., 375° C. to 450° C., 400° C. to 425° C., 400° C. to 450° C., etc.), a pressure of 100 Torr to 1500 Torr (250 Torr to 1000 Torr, 500 Torr to 1000 Torr, 250 Torr to 1250 Torr, 500 Torr to 1250 Torr, etc.), a duration of 1 hr to 15 hr (e.g., 2 hr to 13 hr, 3 hr to 12 hr, etc.), or any combination thereof. In some embodiments, the process conditions should be sufficient for the fluorine of the fluorine component to react with the magnesium present within the substrate to for magnesium fluoride (MgF₂). In some embodiments, the process conditions should be a temperature, a pressure, a duration, or any combination thereof sufficient to cause the fluorine of the fluorine component to react with the magnesium present within the substrate to form MgF₂. In some embodiments, the process conditions may be varied or adjusted to obtain at least one of a predetermined thickness, a predetermined coverage, a predetermined property (e.g., at least one of corrosion resistance, etch resistance, or any combination thereof), or any combination thereof.

In some embodiments, a surface coverage may refer to a percentage of unmasked, exposed surfaces (e.g., a gas-exposed surface) comprising magnesium fluoride. In some embodiments, the exposed surface(s) may also refer to unmasked surface(s). In some embodiments, the surface coverage may be at least 80% to 100%, or any range or subrange therebetween. For example, in some embodiments, the surface coverage may be at least 90%, at least 91%, at least 92% at least 93%, at least 94%, at least 95%, at least 96%, at least 97%, at least 98%, at least 99%, or 100%. In some embodiments, the surface coverage may range from 80% to 100%, and/or any range or subrange therebetween.

In some embodiments, the etch stop layer is a conformal layer. In some embodiments, the etch stop layer is a layer having a substantially uniform thickness or a uniform thickness. In some embodiments, the etch stop layer may be a corrosion resistant layer or may form a corrosion resistant substrate surface. In some embodiments, the etch stop layer may be an etch resistant layer or may form an etch resistant substrate surface. In some embodiments, the etch stop layer may passivate the surface of the substrate. In some embodiments, the etch stop layer may be a protective layer. In some embodiments, the etch stop layer may impart at least one improved surface property.

In some embodiments, the etch stop region may have a thickness of 1 nm to 200 nm, or any range or subrange therebetween. For example, in some embodiments, the etch stop region may have a thickness of 5 nm to 200 nm, 10 nm to 200 nm, 25 nm to 200 nm, 50 nm to 200 nm, 100 nm to 200 nm, 150 nm to 200 nm, 1 nm to 150 nm, 25 nm to 150 nm, 50 nm to 150 nm, 100 nm to 150 nm, 25 nm to 130 nm, 50 nm to 130 nm, 75 nm to 130 nm, and/or any range or subrange therebetween. In some embodiments, the thickness of the etch stop region may be measured by Scanning Electron Microscope (SEM) cross-section, X-ray Photoelectron Spectroscopy (XPS) depth profiling, or Energy Disruptive X-ray Microanalysis (EDAX), among other techniques.

At step 106, the coating may be formed on at least one of the etch stop layer, the substrate, or any combination thereof. In some embodiments, the coating may be formed by exposing the article to one or more precursor gases to form the coating on a surface of the etch stop layer, the substrate, or any combination thereof. In some embodiments, the coating may be formed by a deposition process. In some embodiments, the deposition process may comprise a non-plasma deposition process. In some embodiments, the deposition process may comprise a plasma-free deposition process. In some embodiments, the deposition process may comprise at least one of atomic layer deposition (ALD), chemical vapor deposition (CVD), solution deposition, or physical vapor deposition (PVD). In some embodiments, the deposition process may comprise thermal atomic layer deposition. In some embodiments, the atomic layer deposition may comprise a cyclic atomic layer deposition process to form the coating. In some embodiments, the coating is an atomic layer deposition (ALD) coating or a thermal ALD coating. In some embodiments, the deposition process is a process that forms a conformal coating. In some embodiments, a conformal coating may comprise a coating have a uniform or a substantially uniform thickness.

In some embodiments, the forming may comprise a process sequence for atomic layer deposition. In some embodiments, the process sequence may be one in which the one or more precursors are utilized in a cyclic atomic layer deposition (ALD) process to form the ALD coating or thermal ALD coating. In some embodiments, the exposing may comprise a process sequence of contacting the 3D article with at least a first precursor in a reaction chamber, purging the reaction chamber, contacting the 3D article with at least a second precursor in the reaction chamber, and purging the reaction chamber to complete a cycle. In some embodiments, the forming may comprise from 1 to 5000 cycles. In some embodiments, the forming may comprise 100 to 5000 cycles. In some embodiments, the forming may comprise 50 to 1500 cycles. In some embodiments, the forming may comprise a sufficient number of cycles to achieve a desired thickness, a desired property, or other characteristic.

In some embodiments, the one or more precursor gases may be selected based on the specific ALD coating to be formed. In some embodiments, the one or more precursors comprising trimethylaluminum and ozone may be useful precursor compositions for depositing Al₂O₃. In some embodiments, the one or more precursors comprising trimethylaluminum and water may be useful precursor compositions for depositing Al₂O₃. In some embodiments, the one or more precursors comprising cyclopentadienyl compounds of the metal M or of Ln may be useful precursor compositions for depositing MO or Ln₂O₃ in cyclic ALD processes utilizing ozone (O₃) or water vapor (H₂O). In some embodiments, the one or more precursors comprising beta-diketonates of M or Ln may be useful precursor compositions for depositing MO or Ln₂O₃ in a cyclic ALD process in which reactive pulses of the beta-diketonate metal precursor alternate with pulses of O₃.

For example, in some embodiments, the atomic layer deposition may comprise a process sequence in which trimethylaluminum and ozone are utilized in a cyclic ALD process to form the ALD coating. In some embodiments, the atomic layer deposition may comprise a process sequence in which trimethylaluminum and water are utilized in a cyclic ALD process to form the ALD coating. In some embodiments, the atomic layer deposition may comprise a process sequence in which a cyclopentadienyl M compound and ozone are utilized in a cyclic ALD process to form the ALD coating. In some embodiments, the atomic layer deposition may comprise a process sequence in which a cyclopentadienyl M compound and water are utilized in a cyclic ALD process to form the ALD coating. In some embodiments, the atomic layer deposition may comprise a process sequence in which a M beta-diketonate compound and ozone are utilized in a cyclic ALD process to form the ALD coating. In some embodiments, other metal oxide precursor compounds may be used.

In some embodiments, the one or more precursors comprising trimethylaluminum and ozone may be useful precursor compositions for depositing Al₂O₃. In some embodiments, the one or more precursors comprising trimethylaluminum and water may be useful precursor compositions for depositing Al₂O₃. In some embodiments, the one or more precursors comprising cyclopentadienyl compounds of the metal M or of Ln may be useful precursor compositions for depositing MO or Ln₂O3 in cyclic ALD processes utilizing ozone (O₃) or water vapor (H₂O). In some embodiments, the one or more precursors comprising beta-diketonates of M or Ln may be useful precursor compositions for depositing MO or Ln₂O₃ in a cyclic ALD process in which reactive pulses of the beta-diketonate metal precursor alternate with pulses of O₃.

In some embodiments, one or more precursor ligands may be employed for deposition of the coating. In some embodiments, the one or more precursor ligands may comprise at least one of a hydrogen, a C₁-C₁₀ alkyl, which may be linear or branched, cyclic or acyclic, saturated or unsaturated; an aryl, a heterocycle, an alkoxy, a cycloalkyl, a silyl, a silylalkyl, a silylamide, a trimethylsilyl silyl-substituted alkyl, a trialkylsilyl-substituted alkyne, a trialkylsilylamido-substituted alkyne, a dialkylamide, an ethylene, an acetylene, an alkyne, a substituted alkene, a substituted alkyne, a diene, a cyclopentadienyl allene, an amine, an alkyl amine, a bidentate amine, an ammonia, a RNH₂ (where R is an organo, such as, for example, a hydrocarbyl, substituent), an amidinate, a guanidinate, a diazadiene cyclopentadienyl, an oxime, a hydroxyamine, an acetate, a beta-diketonate, a beta-ketoiminate, a nitrile, a nitrate, a sulfate, a phosphate, a halogen, a hydroxyl, a substituted hydroxyl, any derivative thereof, or any combination thereof.

In some embodiments, the forming may be performed at a temperature of 20° C. to 400° C., or any range or subrange therebetween. For example, in some embodiments, the forming may be performed at a temperature of 25° C. to 400° C., 50° C. to 400° C., 75° C. to 400° C., 100° C. to 400° C., 125° C. to 400° C., 150° C. to 400° C., 175° C. to 400° C., 200° C. to 400° C., 225° C. to 400° C., 250° C. to 400° C., 275° C. to 400° C., 300° C. to 400° C., 325° C. to 400° C., 350° C. to 400° C., 375° C. to 400° C., 20° C. to 375° C., 20° C. to 350° C., 20° C. to 325° C., 20° C. to 300° C., 20° C. to 275° C., 20° C. to 250° C., 20° C. to 225° C., 20° C. to 200° C., 20° C. to 175° C., 20° C. to 150° C., 20° C. to 125° C., 20° C. to 100° C., 20° C. to 75° C., 20° C. to 50° C., 125° C. to 375° C., 150° C. to 350° C., 175° C. to 350° C., 175° C. to 325° C., 200° C. to 350° C., 200° C. to 325° C., 225° C. to 350° C., 225° C. to 325° C., 250° C. to 350° C., 250° C. to 325° C., 275° C. to 350° C., 275° C. to 325° C., 300° C. to 350° C., 300° C. to 325° C., and/or any range or subrange therebetween.

In some embodiments, the deposition process is a process that forms a conformal coating. In some embodiments, a conformal coating may comprise a coating have a uniform or a substantially uniform thickness.

In some embodiments, the coating layer may have a thickness of 1 nm to 50 µm, or any range or subrange therebetween. For example, in some embodiments, the coating layer may have a thickness of less than 5 µm, less than 1 µm, or less than 250 nm. In some embodiments, the coating layer may have a thickness of 100 nm to 250 nm, 1 nm to 4 µm, 1 nm to 3 µm, 1 nm to 2 µm, 1 nm to 1 µm, 1 nm to 900 nm, 1 nm to 850 nm, 1 nm to 800 nm, 1 nm to 750 nm, 1 nm to 700 nm, 1 nm to 650 nm, 1 nm to 600 nm, 1 nm to 550 nm, 1 nm to 450 nm, 1 nm to 400 nm, 1 nm to 350 nm, 1 nm to 300 nm, 1 nm to 250 nm, 1 nm to 200 nm, 1 nm to 150 nm, 1 nm to 100 nm, 1 nm to 50 nm, 50 nm to 5 µm, 100 nm to 5 µm, 200 nm to 5 µm, 300 nm to 5 µm, 400 nm to 5 µm, 500 nm to 5 µm, 600 nm to 5 µm, 700 nm to 5 µm, 800 nm to 5 µm, 900 nm to 5 µm, 1 µm to 5 µm, 2 µm to 5 µm, 3 µm to 5 µm, 4 µm to 5 µm, 1 nm to 750 nm, 1 nm to 500 nm, 2 nm to 500 nm, 1 nm to 250 nm, 20 nm to 125 nm, 20 nm to 250 nm, 20 nm to 500 nm, 50 nm to 500 nm, 50 nm to 400 nm, 50 nm to 300 nm, 50 nm to 200 nm, 15 nm to 200 nm, 20 nm to 50 nm, 10 nm to 40 nm, 30 nm to 50 nm, 1 nm to 5 µm, 1 µm to 5 µm, 1 µm to 4 µm, 1 µm to 3 µm, 1 µm to 2 µm, 5 nm to 5 µm, 1 nm to 1 µm, and/or any range or subrange therebetween.

In some embodiments, the coating may comprise at least one second metal component. In some embodiments, the at least one second metal component may comprise, consist of, or consist essentially of at least one of elemental metal, a metal alloy, a metal compound (e.g., a metal oxide compound), or any combination thereof. In some embodiments, the at least one second metal component may comprise, consist of, or consist essentially of at least one of magnesium, aluminum, vanadium, iron, nickel, chromium, zinc, molybdenum, titanium, lithium, copper, manganese, or any combination thereof. In some embodiments, the at least one second metal component may be selected from the group consisting of at least one of magnesium, aluminum, vanadium, iron, nickel, chromium, zinc, molybdenum, titanium, lithium, copper, manganese, silicon, copper, manganese, magnesium oxide, or any combination thereof. In some embodiments, the at least one second metal component may comprise at least one metal that is the same as a metal included in the first metal component of the substrate. In some embodiments, for example, in some embodiments, the first metal component and the second component comprise aluminum, or any one or more of the other metals.

In some embodiments, the coating may comprise, consist of, or consist essentially of, or may be selected from the group consisting of, at least one of alumina, yttria, titania, zirconia, tantalum oxide, or any combination thereof. In some embodiments, the coating may comprise, consist of, or consist essentially of, or may be selected from the group consisting of, one or more of Al₂O₃; oxides of the formula MO, wherein M is Ca, Mg, or Be; oxides of the formula M’O₂, wherein M′ is a stoichiometrically acceptable metal; oxides of the formula Re₂O₃, wherein Re is a rare earth element, such as, for example, a lanthanide element; and oxides of formula TaₓO_{y}, where x is greater than 0 and y is greater than 0. In some embodiments, the lanthanide element may comprise, consist of, or consist essentially of La, Sc, or Y. In some embodiments, the coating may comprise, consist of, or consist essentially of, or may be selected from the group consisting of, at least one of alumina, aluminum-oxy nitride, yttria, yttria-alumina, silicon oxide, silicon oxynitride, transition metal oxides, transition metal oxy-nitrides, rare earth metal oxides, rare earth metal oxy-nitrides, or any combination thereof. In some embodiments, the method further comprises fluorinating the coating layer to form a coating layer comprising at least one of YOF, YF₃, or any combination thereof.

In some embodiments, the article may be a component of a semiconductor manufacturing tool, such as, for example and without limitation, at least one of a process chamber, a sidewall, a flow head (e.g., a showerhead), a shield, a tray, a support, a nozzle, a valve, a conduit, a stage for handling or holding an object, a wafer handling fixture, a ceramic wafer carrier, a wafer holder, a susceptor, a spindle, a chuck, a ring, a baffle, a fastener (e.g., a (threaded) screw, a (threaded) nut, a bolt, a clamp, a rivet, etc.), a membrane, a filter, a three-dimensional network, a conduit (e.g., a gas line), a manifold (e.g., a gas manifold), or any combination thereof.

In some embodiments, the magnesium fluoride passivation layer may be biocompatible such that the article may be useful as an implantable medical device or any component thereof. For example, in other embodiments, the article may be a medical device or a component of a medical device, such as, for example and without limitation, at least one of a medical instrument, a medical implant, or an article having a medical use. Non-limiting examples of medical devices and/or components thereof, include at least one of prosthetics (e.g., knees, joints, shoulders, hips, etc.), dental braces, hearing aids, screws, plates, catheters, tubes, valves, enclosures, wires, stents, connectors, or any combination thereof, and the like.

Some embodiments of the present disclosure relate to articles having a removable coating. In some embodiments, the articles comprise articles formed according to the methods of the present disclosure, such as, for example, the method of FIG. 1. It thus will be appreciated that the articles may comprise any of the features disclosed herein, including those disclosed above and elsewhere herein.

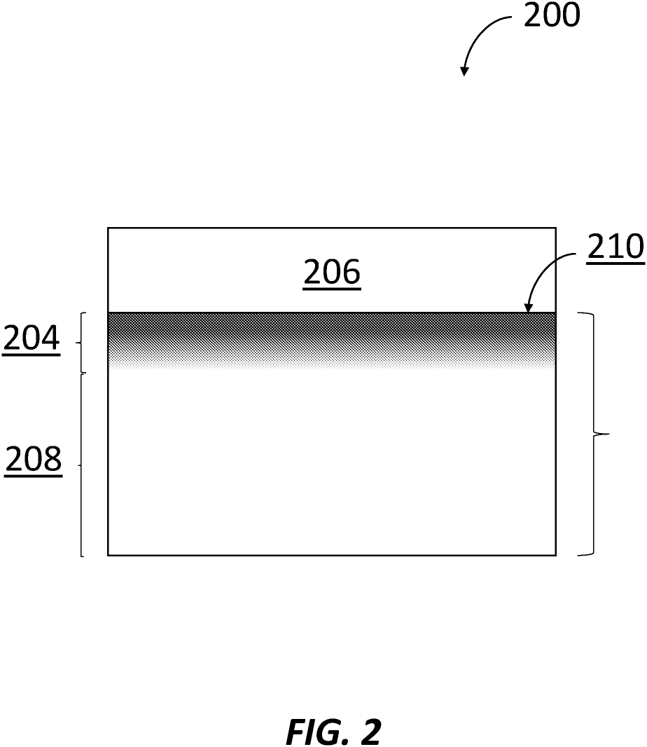

FIG. 2 is a schematic diagram of an article including a removable coating, according to some embodiments of the present disclosure. As shown in FIG. 2, the article may comprise a substrate 202, an etch stop layer 204, and a coating 206. In some embodiments, the etch stop layer 204 may be at the surface 210 of the substrate 202. For example, in some embodiments, the etch stop layer 204 may be an etch stop region of the substrate 202 that extends from the surface 210 of the substrate 202 to a depth within the substrate 202. In some of these embodiments, the substrate 202 may further comprise a bulk region 208, wherein the bulk region 208 is a region of the substrate 202 that is not the region defining the etch stop layer 204. In some embodiments, the etch stop layer 204 may be on the surface 210 of the substrate 202. In some embodiments, the coating 206 may be on the surface 210 of the etch stop layer 204. In some embodiments, the coating 206 may be on the surface of the substrate 202. In some embodiments, the coating 206 may be on the surface of the etch stop layer 204, wherein the etch stop layer 204 is formed at the surface of the substrate 202.

In some embodiments, the etch stop layer 204, being positioned or located between the substrate 202 and the coating 206, may permit removal of the coating 206 (e.g., by etching, such as, for example and without limitation, at least one of dry etching, wet etching, or any combination thereof) without degrading or chemically modifying the substrate 202 to a state or condition that is not commercially useful. For example, in some embodiments, the substrate 202 and the coating 206 may be chemically similar such that removing the coating 206 in the absence of the etch stop layer 204 results in removing at least a portion of the substrate 202. In some embodiments, the etch stop layer 204 may passivate the surface of the substrate 202 such that removing the coating 206 does not result in any appreciable removal of the substrate 202 or, if at least some removal of the substrate results, the extent of the removal is acceptable for commercial purposes. In this way, the etch stop layer 204 may be effective as a chemically resistant layer that permits refurbishing and/or reworking of articles.

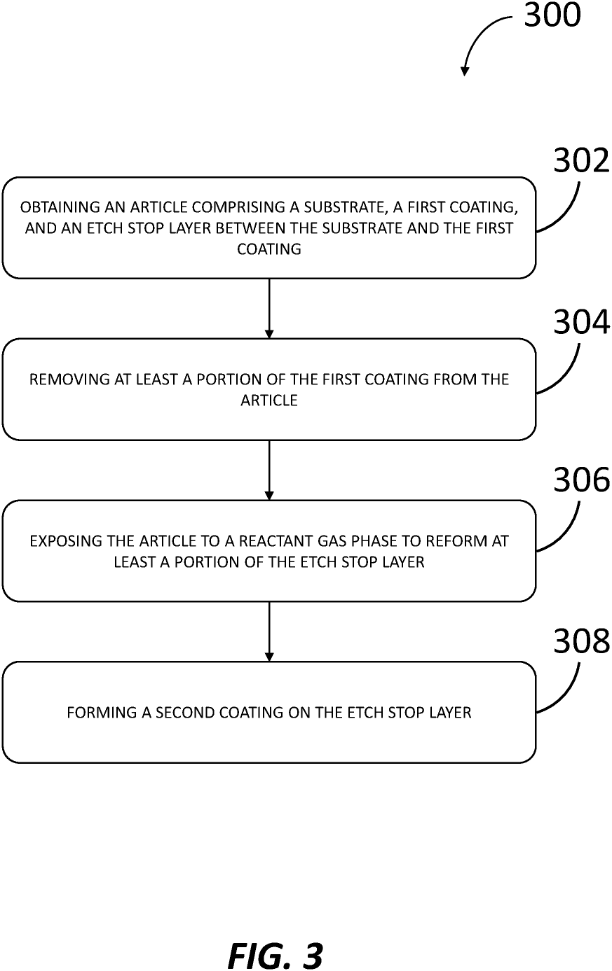

FIG. 3 is a flowchart of a method for removing a coating from an article, according to some embodiments of the present disclosure. As shown in FIG. 3, the method 300 for removing a coating from an article may comprise one or more of the following steps: a step 302 of obtaining an article, wherein the article comprises a substrate, a first coating, and an etch stop layer between the substrate and the first coating; a step 304 of removing at least a portion of the first coating from the article; a step 306 of exposing the article to a reactive gas phase to reform at least a portion of the etch stop layer; and a step 308 of forming a second coating on the etch stop layer. In some embodiments, the first coating is a spent coating and the second coating is a replacement coating.

At step 302, in some embodiments, the article may be obtained. As mentioned above, in some embodiments, the article may comprise a substrate, a first coating, and an etch stop layer between the substrate and the first coating. In some embodiments, the article obtained may comprise any one or more of the articles formed according to the methods of the present disclosure (e.g., the articles formed according to the method of FIG. 1) and the articles of the present disclosure (e.g., the articles depicted in the schematic diagram of FIG. 2). In some embodiments, the article obtained may comprise an article for reworking. In some embodiments, the article for reworking may be an article in which the first coating is formed with a defect due, for example, to a fabrication error. In some embodiments, the article obtained may comprise an article for refurbishing. In some embodiments, the article for refurbishing may be an article in which the first coating has degraded through use (e.g., repeated use) in a process (e.g., a semiconductor fabrication process, a microelectronic fabrication process, etc.). In some embodiments, the first coating may be any coating that is to be at least one of reworked, removed, replaced, refurbished (e.g., a coating that has been used or processed one or more times and is considered to be in an “end of life” condition), or any combination thereof. In some embodiments, the first coating may be a spent coating, wherein the spent coating may be any coating that has a defect and/or that has been degraded (e.g., through use).

For example, in some embodiments, the first coating may comprise a coating that is to be refurbished. In some embodiments, the coating to be refurbished may be a coating in a state or condition that is deleterious to the structure, material, use, or operation of the article (e.g., that renders the article unsuitable for commercial purposes). Accordingly, the first coating may be described in reference to a previous state or condition. For example, in some embodiments, the previous state or previous condition of the first coating may be a coating prepared according to the methods of the present disclosure (e.g., step 106 of FIG. 1). In some of these embodiments, the first coating is any coating having at least one property, feature, element, characteristic, or composition that is different from the coating in the previous state or the previous condition. In some embodiments, the first coating is a coating that has been used at least once in a process (e.g., a semiconductor fabrication process, etc.). In some embodiments, the difference may be at least one of a different chemical composition, a different surface morphology, a different thickness, or any combination thereof. In some embodiments, the first coating may comprise a coating that is to be reworked. In some embodiments, the coating that is to be reworked may be any coating that is poorly fabricated. For example, in some embodiments, the first coating may be a coating that does not meet a specification for an application. In some embodiments, the first coating may be a coating having a defect, such as a defect created during formation of the coating. In some embodiments, the coating to be reworked is a coating that has not been used in any process.

In some embodiments, the first coating may be a coating that has been chemically modified from a previous state. In some embodiments, the first coating may be a coating having a surface that has been modified from a previous state. In some embodiments, the first coating may be a coating having a thickness that has been modified from a previous state. In some embodiments, the first coating may be a coating having a non-uniform thickness. In some embodiments, the first coating may be a coating not meeting a specification for an application. In some embodiments, the first coating may be a coating having a fabrication defect.

At step 304, in some embodiments, at least a portion of the first coating may be removed from the article. In some embodiments, the removing may comprise contacting the first coating with an etchant to remove at least a portion of the first coating from the article. In some embodiments, the etchant may comprise any etchant that preferentially etches the first coating over the etch stop layer. In some embodiments, the removal of the first coating may proceed by at least one of dry etching, wet etching, or any combination thereof. In some embodiments, the etchant may remove the first coating from the article in its entirety. In some embodiments, the etchant may remove at least a portion of the first coating from the article. In some embodiments, the etch stop layer prevents or at least reduces the extent to which the substrate is etched during etching of the first coating. In some embodiments, the etchant may remove at least a portion of the etch stop layer. In some embodiments, the first coating may be removed by processes other than etching. In some embodiments, for example, the first coating may be removed by, either applied alone or in combination with, a mechanical removal process (e.g., blasting, polishing, lapping, ion sputtering, etc.) or a stress induced separation (e.g., delamination). In some embodiments, the first coating may be removed without applying any mechanical removal process (e.g., blasting, polishing, lapping, ion sputtering, etc.) or a stress induced separation (e.g., delamination).

In some embodiments, the etchant may have a selectivity for the first coating over at least one of the etch stop layer, the substrate, or any combination thereof. In some embodiments, the selectivity may be defined as a ratio of a thickness of the etch stop layer removed to a thickness of the substrate removed. In some embodiments, the selectivity of the etchant may be at least 1.01:1 to 20:1, or any range or subrange therebetween. For example, in some embodiments, the selectivity of the etchant may be 2:1 to 5:1, 2:1 to 10:1, 5:1 to 10:1, and/or any range or subrange therebetween. In some embodiments, the selectivity of the etchant may be at least 2:1, at least 3:1, at least 4:1, at least 5:1, at least 6:1, at least 7:1, at least 8:1, at least 9:1, at least 10:1, at least 11:1, and/or any range or subrange therebetween.

At step 306, in some embodiments, the article may be exposed to the reactive gas phase to reform at least a portion of the etch stop layer. In some embodiments, the step 306 is optional. For example, in some embodiments, the step 306 may be performed in instances where at least a portion of the etch stop layer may be removed by the etchant. In some embodiments, the step 306 may be performed in instances where at least a portion of the surface of the substrate may not comprise magnesium fluoride. In some embodiments, the step 306 may be performed in instances where at least a portion of the etch stop layer or the surface of the substrate requires reforming or repairing of the etch stop layer, the magnesium fluoride, or any combination thereof. In some embodiments, the step of exposing the article to the reactive gas phase to reform the etch stop layer may be performed according to the methods of the present disclosure. For example, in some embodiments, the forming step may be performed similar to, or the same as, the step 104 of FIG. 1.

At step 308, in some embodiments, the second coating may be reformed on at least one of the substrate, the etch stop layer, or any combination thereof. In some embodiments, the second coating may be a replacement coating. In some embodiments, the second coating may produce an article suitable for commercial purposes. In some embodiments, reforming the second coating or the replacement coating on at least one of the substrate, the etch stop layer, or any combination thereof produces a reworked or refurbished article. In some embodiments, the step of reforming the second coating on at least one of the substrate, the etch stop layer, or any combination thereof may be performed according to the methods of the present disclosure. For example, in some embodiments, the reforming step may be performed similar to, or the same as, the step 106 of FIG. 1.

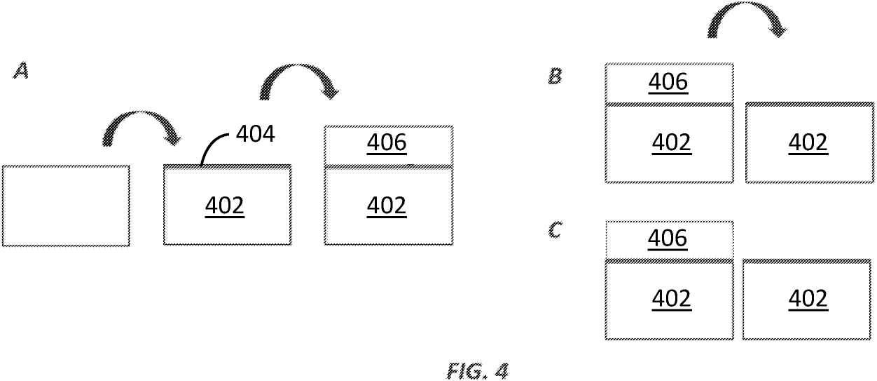

FIG. 4 is a schematic diagram of a process for (A) forming an article including a removable coating, (B) reworking the article, and (C) refurbishing the article, according to some embodiments of the present disclosure. As shown in (A) of FIG. 4, a substrate 402 comprising a metal alloy (e.g., an aluminum alloy) is shown. In some embodiments, the metal alloy is an aluminum alloy comprising at least 90% aluminum. In some embodiments, the aluminum alloy may comprise 95% to 99% by weight of aluminum, greater than 0% and less than 1% by weight of silicon, greater than 0% and less than 1% by weight of copper, greater than 0% and less than 1% by weight of chromium, and greater than 0% to 2% by weight of magnesium, wherein the % by weight is based on a total weight of the substrate 402. In some embodiments, an etch stop layer 404 may be formed at and/or below the surface of the substrate 402. In some embodiments, a coating 406 (e.g., an atomic layer deposition (ALD) coating comprising alumina, or an alumina ALD coating) may be formed on the surface of the substrate 402, the surface of the etch stop layer 404, or both the surface of the substrate 402 and the surface of the etch stop layer 404 to obtain an article including a removable coating.

As shown in (B) of FIG. 4, in some embodiments, the coating 406 or the process of forming the coating 406 may have a defect or error. In some embodiments, the coating 406 may be reworked. For example, in some embodiments, the coating 406 is an alumina ALD coating having an error or defect. In some embodiments, the alumina ALD coating 406 may be removed by a wet chemical removal process (e.g., wet etching). In some embodiments, by removing the alumina ALD coating 406 having the error or defect, a replacement alumina ALD coating (not shown) may be formed on the surface of the substrate 402/etch stop layer 404.

As shown in (C) FIG. 4, in some embodiments, the article may be used (e.g., may reach end of life, or may have a chemically altered composition, among other things, as described above). In some embodiments, the coating 406 may be refurbished. For example, in some embodiments, the coating 406 is an alumina ALD coating that has been used in one or more processes. In some embodiments, the alumina ALD coating 406 may be removed by a wet chemical removal process (e.g., wet etching). In some embodiments, by removing the alumina ALD coating 406 having the modification from a previous state or condition, a replacement ALD coating (not shown) may be formed on the surface of the substrate 402/etch stop layer 404.

What is claimed is:

1. A method for removing a coating from an article, the method comprising:
obtaining an article,
wherein the article comprises:
a substrate comprising a magnesium-containing metal body, wherein the magnesium-containing metal body comprises a first metal component;
a coating comprising a second metal component; and
an etch stop layer, wherein the etch stop layer comprises magnesium fluoride and is located between the magnesium-containing metal body and the coating; and
removing at least a portion of the coating from the article.

2. The method according to claim 1, wherein the substrate comprises at least one of a plenum, a trench, a structure defining a hole, a structure defining a channel, a structure defining a cavity, or any combination thereof.

3. The method according to claim 1, wherein the substrate is not a wafer substrate.

4. The method according to claim 1, wherein the substrate is not an integrated circuit.

5. The method according to claim 1, wherein the coating is at least one of:
a coating that has been chemically modified from a previous state,
a coating having a surface that has been modified from a previous state,
a coating having a thickness that has been modified from a previous state,
a coating having a non-uniform thickness,
a coating not meeting a specification for an application,
a coating having a fabrication defect, or
any combination thereof.

6. The method according to claim 1, wherein the second metal component and the first metal component both comprise at least one of magnesium, aluminum, vanadium, iron, nickel, chromium, zinc, molybdenum, titanium, lithium, copper, manganese, silicon, copper, manganese, or any combination thereof.

7. The method according to claim 1, wherein the first metal component comprises aluminum; and the second metal component comprises aluminum.

8. The method according to claim 1, wherein the etch stop layer is an etch stop region located at and below a surface of the substrate.

9. The method according to claim 1, wherein the removing comprises contacting the coating with an etchant.

10. The method according to claim 9, wherein the etchant removes at least a portion of the etch stop layer.

11. The method according to claim 10, further comprising:
exposing the article to a reactive gas phase to reform at least a portion of the etch stop layer,
wherein the reactive gas phase comprises a fluorine component.

12. The method according to claim 11, wherein the fluorine component comprises or is derived from at least one of CF₄, C₂F₄, C₃F₆, C₄F₈, CHF₃, C₂H₂F₂, C₂F₆, HF, CH₃F, polymerized perfluoroalkylethylene having a C₁-C₁₀ perfluoroalkyl group, polytetrafluoroethylene (PTFE), tetrafluoroethylene/perfluoro(alkyl vinyl ether) copolymer (PFA), tetrafluoroethylene/hexafluoropropylene copolymer (FEP), tetrafluoroethylene/perfluoro(alkyl vinyl ether)/hexafluoropropylene copolymer (EPA), polyhexafluoropropylene, ethylene/tetrafluoroethylene copolymer (ETFE), poly trifluoroethylene, polyvinylidene fluoride (PVDF), polyvinyl fluoride (PVF), polychlorotrifluoroethylene (PCTFE), ethylene/chlorotrifluoroethylene copolymer (ECTFE), or any combination thereof.

13. The method according to claim 11, wherein the fluorine component of the reactive gas phase reacts with magnesium present within the magnesium-containing metal body to reform the etch stop layer.

14. The method according to claim 1, wherein a ratio of a thickness of coating removed to a thickness of etch stop layer removed is at least 2:1.

15. The method according to claim 1, wherein the etch stop layer has a uniform thickness.

16. The method according to claim 1, further comprising forming a replacement coating on the etch stop layer.

17. The method according to claim 16, wherein the replacement coating is a thermal atomic layer deposition (ALD) coating.

18. The method according to claim 16, wherein the replacement coating comprises at least one of alumina, yttria, titania, zirconia, tantalum oxide, or any combination thereof.

19. A method for forming an article, the method comprising:
obtaining a substrate,
wherein the substrate comprises a magnesium-containing metal body,
wherein the magnesium-containing metal body comprises a first metal component;
exposing the substrate to a reactive gas phase to form an etch stop layer at and below a surface of the substrate,
wherein the reactive gas phase comprises a fluorine component that reacts with magnesium of the magnesium-containing metal body to form magnesium fluoride; and
forming a coating on the etch stop layer,
wherein the coating comprises a second metal component.

20. An article comprising:
a substrate,
wherein the substrate comprises a magnesium-containing metal body,
wherein the magnesium-containing metal body comprises a first metal component,
wherein the substrate is not a wafer substrate,
wherein the substrate is not an integrated circuit;
a coating,
wherein the coating comprises a second metal component; and
an etch stop layer located between the substrate and the coating,
wherein the etch stop layer comprises magnesium fluoride formed at and below a surface of the substrate.
